(19) United States
(12) Patent Application Publication
(10) Pub. No.: US 2025/0236526 A1
(43) Pub. Date: Jul. 24, 2025

(54) COLLOIDAL SILICA AND PRODUCTION METHOD THEREFOR

(71) Applicant: TAMA CHEMICALS CO., LTD., Kawasaki City, Kanagawa (JP)

(72) Inventors: Ryuichi OHYAMA, Kawasaki City (JP); Akihito YASHIRO, Kawasaki City (JP); Tsukasa NISHIMORI, Kawasaki City (JP); Kotaro MIZUTA, Kawasaki City (JP); Takanari AYABE, Kawasaki City (JP)

(73) Assignee: TAMA CHEMICALS CO., LTD., Kawasaki City, Kanagawa (JP)

(21) Appl. No.: 18/853,373

(22) PCT Filed: Apr. 28, 2023
(86) PCT No.: PCT/JP2023/016818

§ 371 Date: Oct. 1, 2024

(30) Foreign Application Priority Data
May 13, 2022 (JP) 2022-079218

(51) Int. Cl. C01B 33/141; C09K 3/14

(52) U.S. Cl. CPC C01B 33/141; C09K 3/1409; C01P 2004/03; C01P 2004/04; C01P 2004/61; C01P 2004/62; C01P 2004/64

(57) ABSTRACT

There is provided a colloidal silica with reduced fine particles and a production method therefor. In the colloidal silica, the number distribution ratio of fine particles having a particle diameter of 50% or less of the particle diameter median value based on the equivalent circle diameter (Heywood diameter) by image analysis using an electron microscope is 1% or less. Also, the method for producing such a colloidal silica is a method in which an easily hydrolyzable organosilicate is fed to and allowed to react with a reaction solution containing a hydrolysis catalyst composed of one or a mixture of two or more selected from organic amines, wherein the feeding is performed with the feeding port of the easily hydrolyzable organosilicate immersed under the surface of the reaction solution.

### TECHNICAL FIELD

The present invention relates to a colloidal silica and a production method therefor.

### BACKGROUND ART

As methods for industrially producing colloidal silica with high purity, there have been proposed and implemented a method in which a sodium silicate aqueous solution is ion-exchanged, a thermal decomposition method of silicon tetrachloride, a method in which organosilicate is hydrolyzed in a water-alcohol mixed solvent in the presence of an acid catalyst or an alkali catalyst, and other methods. In the method in which organosilicate is hydrolyzed, those with high purity can be used as the organosilicate, catalyst, solvent, and others used in the reaction, and thus the amount of impurities derived from these raw materials and others is extremely small. Therefore, this method is particularly suited for producing high purity colloidal silica with a low metallic impurity content, and several methods have been proposed with respect to this hydrolysis method of organosilicate.

Here, for colloidal silica used in various applications, especially colloidal silica used in the field of semiconductor wafer abrasives, for example, colloidal silica with a variety of slightly different compositional features and properties is in demand, since various types of metal wiring, oxide films, and others are present on a single wafer due to the high integration of LSIs today, and also since semiconductor wafers require polishing performance suited to each of them.

Also, for colloidal silica used in applications such as binders for hard coating agents, ceramics and so on, chromic acid-based metal surface treatment agents, and ground improving injection agents, where even a small amount of alkali metal impurities are not desired, acidic colloidal silica is required. Several proposals have been known for the production method of such acidic colloidal silica as well.

For example, Patent Literature 1 discloses a method for producing an acidic silica sol by first preparing an alkaline silica sol containing an aluminum compound, and then treating this aluminum compound-containing alkaline silica sol with a cation exchange resin for dealkalization. Also, Patent Literature 2 discloses a method for producing a stable acidic silica sol with a pH of 2 to 5 and a particle diameter of 4 to 30 by adding an alkali aluminate aqueous solution to a silica sol with a particle diameter of 4 to 30 and a pH of 2 to 9 such that the Al₂O₃/SiO₂ molar ratio is 0.0006 to 0.004, which is then brought into contact with an ion-exchange resin.

Furthermore, Patent Literature 3 discloses a method of producing a modified colloidal silica with high purity that does not agglomerate or gelate even in an acidic dispersion medium, is stably dispersible for a long period of time, and has an extremely low metallic impurity content, wherein a colloidal silica obtained by hydrolysis and condensation of a hydrolyzable silicon compound is modified with a modifying agent such as a silane coupling agent.

However, in the methods described in Patent Literature 1 and Patent Literature 2, an aluminum compound-containing alkaline silica sol must be once prepared and then treated with an ion exchange resin for dealkalization, which increases the production costs, and there are also problems of contamination by the ion exchange resin itself and limitations in ion removal during the ion exchange. Also, in the method described in Patent Literature 3, the surface of the colloidal silica obtained is modified by a modifying agent and may not be suited for the desired application, and there is also the problem of contamination from the modifying agent.

Then, in order to solve such problems, the present inventors have investigated a method that enables easy production of a colloidal silica having predetermined properties, such as a spherical colloidal silica that does not require special post-treatments such as an acid treatment, an ion exchange treatment, and even a modification treatment, that has an extremely low content of metallic impurities including alkali metals, and that has an average particle diameter in the range of 5 to 500 nm, a standard deviation of 20 or less, and a polydispersity index of 0.15 or less, as determined by particle size distribution analysis with an electron microscope. As a result, the present inventors have proposed that a neutral colloidal silica with a pH of 5 to 8 can be easily produced without performing any special post-treatments such as an acid treatment and an ion exchange treatment, by using an easily hydrolyzable organosilicate with a high hydrolysis rate, using a specific hydrolysis catalyst as the hydrolysis catalyst, and by adding this hydrolysis catalyst for a reaction such that at least the proportion of the hydrolysis catalyst (A) to silica (B) {residual catalyst molar ratio (A/B)} in the reaction mixture when the reaction is completed is at or below a predetermined value (Patent Literature 4).

By the way, in the above conventional production method by the present inventors, the procedure of feeding the raw material, easily hydrolyzable organosilicate, which is the silica source, to the reaction solution containing water and the hydrolysis catalyst at a predetermined temperature for the reaction is required. Normally, in order to ensure that the silica source is fed (to prevent contact with water and the catalyst near the nozzle and to prevent side reactions), the feeding port for the feeding is placed at a height as far away from the surface of the reaction solution as possible, and the silica source is fed and poured from an aerial part (hereinafter, this may be referred to as “aerial pouring” or the like).

### CITATION LIST

### Patent Literature

Patent Literature 1: JPH4-55126 B

Patent Literature 2: JPH6-199515 A

Patent Literature 3: JP2005-162533 A

Patent Literature 4: JP2007-153732 A

Patent Literature 5: JP2020-073445 A

Patent Literature 6: JP2021-116209 A

### SUMMARY OF INVENTION

### Technical Problem

However, when the silica source is poured from the aerial part as in the conventional method, especially in the case of easily volatile silica sources, not a little amount of the silica source scatters to the surroundings from the feeding port and the surface of the reaction solution. The silica source that scatters to the surroundings, for example, adheres to the walls of the reaction vessel, causing stains and also leading to a decrease in yield and so on. As a result of diligent investigations, the present inventors have confirmed the harmful influence of such a silica source that scatters, which causes contact and side reactions with water droplets adhering to surrounding walls and other surfaces, resulting in production of undesired colloidal silica particulates. It has then been confirmed that when such colloidal silica particulates produced as a result of side reactions fall into the reaction solution along with water droplets, they cause a product in which colloidal silica fine particles that have undergone particle growth with behavior different from that of the normally targeted reaction (hereinafter, these and the fine particles defined based on the image analysis described later may be collectively expressed as “fine particles”) are mixed in. Moreover, when such a colloidal silica in which fine particles are mixed in is subjected to particle growth as seed particles to obtain a colloidal silica with a larger particle diameter, undesired fine particles are present at the same proportion. There is also concern that such a colloidal silica in which undesired fine particles are mixed in and the particle diameter is uneven may cause the harmful influence of non-uniformity in, for example, polishing and micromachining applications.

Then, as a result of diligent investigations to solve such problems in the conventional method, the present inventors have found that by improving the method of feeding the silica source to the reaction solution, a colloidal silica with a reduced proportion of fine particles can be obtained, the yield can be improved, and moreover, side reactions and stains in the reaction vessel can be reduced, thereby reducing the burden of cleaning and other maintenance work, and have completed the present invention.

Accordingly, an object of the present invention is to provide a colloidal silica with a reduced proportion of fine particles and a production method therefor.

Note that there are several reports on colloidal silicas with reduced fine particles (for example, Patent Literature 5 and Patent Literature 6), but Patent Literature 5 is concerned with a modified colloidal silica. Also, in Patent Literature 6, the definition of fine particles is not clear, and the proportion of fine particles is actually about 2 to 4% by area, which is not necessarily a sufficient reduction of fine particles.

### Solution to Problem

That is, the gist of the present invention is as follows.
(1) A colloidal silica, wherein a number distribution ratio of fine particles having a particle diameter of 50% or less of a particle diameter median value based on an equivalent circle diameter (Heywood diameter) by image analysis using an electron microscope is 1% or less.
(2) The colloidal silica according to (1), which is based on image analysis with a scanning electron microscope (SEM) and a scanning transmission electron microscope (STEM).
(3) An abrasive comprising the colloidal silica according to (1) or (2).
(4) A method for producing a colloidal silica, in which an easily hydrolyzable organosilicate is fed to and allowed to react with a reaction solution containing a hydrolysis catalyst composed of one or a mixture of two or more selected from organic amines,
   wherein the feeding is performed with a feeding port of the easily hydrolyzable organosilicate immersed under a surface of the reaction solution.
(5) The method for producing a colloidal silica according to (4), wherein a length of the feeding port of the easily hydrolyzable organosilicate immersed under a surface of the reaction solution is three or more times an outer diameter of the feeding port.
(6) The method for producing a colloidal silica according to (4) or (5), wherein the easily hydrolyzable organosilicate is fed together with an inert gas.
(7) The method for producing a colloidal silica according to (6), wherein a flow rate (L) of the inert gas relative to an amount (kg) of the easily hydrolyzable organosilicate fed is 1 to 10000 L/kg.
(8) The method for producing a colloidal silica according to (4) or (5),
   wherein a nozzle having an inner/outer double pipe structure with an outer pipe and an inner pipe inserted into the outer pipe is used as a means of feeding the easily hydrolyzable organosilicate, and
   the inner pipe is fed with the easily hydrolyzable organosilicate and the outer pipe is fed with an inert gas.
(9) The method for producing a colloidal silica according to (8), wherein a ratio of an inner diameter (O) of the outer pipe feeding the inert gas relative to an outer diameter (I) of the inner pipe feeding the easily hydrolyzable organosilicate, O/I, is 2 to 7.
(10) The method for producing a colloidal silica according to (8), wherein a difference in length between the inner pipe feeding the easily hydrolyzable organosilicate and the outer pipe feeding the inert gas (outer pipe-inner pipe) is an outer diameter of the outer pipe or more, and is one or more times and ten or less times the outer diameter of the outer pipe.
(11) The method for producing a colloidal silica according to (4) or (5), wherein the easily hydrolyzable organosilicate is trimethyl silicate, tetramethyl silicate, triethyl silicate, or methyl trimethyl silicate.
(12) The method for producing a colloidal silica according to (4) or (5), wherein the organic amines are one or a mixture of two or more selected from quaternary ammoniums, tertiary amines, secondary amines, and primary amines, as well as carbonates, bicarbonates, and silicates thereof.
(13) The method for producing a colloidal silica according to (6), wherein the inert gas is nitrogen, argon, and/or helium.
(14) A method for producing a colloidal silica, in which a colloidal silica is produced by the method according to (4) or (5), and then using the colloidal silica as seed particles, an easily hydrolyzable organosilicate is fed to and allowed to react with a reaction solution containing the seed particles and the hydrolysis catalyst to produce a grown colloidal silica with a grown particle diameter.
(15) The method for producing a colloidal silica according to (14), in which seed particles of colloidal silica with a particle diameter median value based on an equivalent circle diameter by image analysis using an electron microscope of 30 nm or less are used and allowed to react at a silica content concentration of 13% by mass or less in a reaction system to produce a grown colloidal silica in which the particle diameter median value is greater than 30 nm and 1 mm or less.

### Advantageous Effects of Invention

According to the present invention, a colloidal silica with reduced fine particles can be obtained. The yield can also be improved, and side reactions and stains in the reaction vessel can be reduced, thereby reducing the burden of cleaning and other maintenance work. Furthermore, since the particle diameter can be made uniform, for example, it contributes to improved efficiency in polishing and micromachining, as well as to production of large particles (“grown particles”) with a uniform particle diameter. The colloidal silica of the present invention is suitable for applications such as abrasives (silicon wafers, hard disks, and others), coating agents (eyeglasses, displays, building materials, paper, and others), and binders (ceramics, catalysts, and others), for example.

### BRIEF DESCRIPTION OF DRAWINGS

FIG. 1 is a schematic diagram illustrating a reaction vessel and a double pipe structure used therefor.

FIG. 2 shows each of the STEM (a) and SEM (b) images (magnification: 100,000) of the colloidal silica obtained in Example 1.

FIG. 3 shows the STEM analysis image (c) and the particle diameter distribution (d) of the colloidal silica obtained in Example 1.

FIG. 4 shows each of the STEM (a) and SEM (b) images (magnification: 100,000) of the colloidal silica obtained in Example 2.

FIG. 5 shows the STEM analysis image (c) and the particle diameter distribution (d) of the colloidal silica obtained in Example 2.

FIG. 6 shows each of the STEM (a) and SEM (b) images (magnification: 50,000) of the colloidal silica obtained in Example 3.

FIG. 7 shows the STEM analysis image (c) and the particle diameter distribution (d) of the colloidal silica obtained in Example 3.

FIG. 8 shows each of the STEM (a) and SEM (b) images (magnification: 100,000) of the colloidal silica obtained in Comparative Example 1.

FIG. 9 shows the STEM analysis image (c) and the particle diameter distribution (d) of the colloidal silica obtained in Comparative Example 1.

FIG. 10 shows each of the STEM (a) and SEM (b) images (magnification: 100,000) of the colloidal silica obtained in Comparative Example 2.

FIG. 11 shows the STEM analysis image (c) and the particle diameter distribution (d) of the colloidal silica obtained in Comparative Example 2.

FIG. 12 shows each of the STEM (a) and SEM (b) images (magnification: 50,000) of the colloidal silica obtained in Comparative Example 3.

FIG. 13 shows the STEM analysis image (c) and the particle diameter distribution (d) of the colloidal silica obtained in Comparative Example 3.

FIG. 14 shows each of the STEM (a) and SEM (b) images (magnification: 100,000) of the colloidal silica obtained in Example 10.

FIG. 15 shows the STEM analysis image (c) and the particle diameter distribution (d) of the colloidal silica obtained in Example 10.

FIG. 16 shows each of the STEM (a) and SEM (b) images (magnification: 100,000) of the colloidal silica obtained in Comparative Example 4.

FIG. 17 shows the STEM analysis image (c) and the particle diameter distribution (d) of the colloidal silica obtained in Comparative Example 4.

### DESCRIPTION OF EMBODIMENTS

### <Colloidal Silica>

As described above, in the colloidal silica of the present invention, the number distribution ratio of fine particles having a particle diameter of 50% or less of the particle diameter median value based on the equivalent circle diameter by image analysis using an electron microscope is 1% or less. Preferably, the number distribution ratio of fine particles is 0.5% or less, and more preferably, fine particles are close to 0%.

The equivalent circle diameter, also called Heywood diameter, may be in accordance with JIS Z 8827-1:2008 Particle size analysis-Image analysis methods-. When measuring particles of various shapes, such as colloidal silica particles with irregularities on the surface or particles that are aggregated and have a constriction, there are problems with manual measurement, such as the tendency for errors to occur and the time required to perform the measurement. Therefore, based on such a standardized equivalent circle diameter, the amount of fine particles present can be objectively evaluated, which is preferable.

There are no restrictions on the electron microscope to be used as long as it can acquire images applicable to measurement and analysis of the equivalent circle diameter. For example, known electron microscopes such as scanning electron microscopes (SEMs), transmission electron microscopes (TEMs), and scanning transmission electron microscopes (STEMs) can be used without any restrictions. Preferably, a SEM or TEM and a STEM may be used in combination, and more preferably, a SEM and a STEM may be used in combination. In analysis of particles, particles are identified by binarization, which divides particles and non-particles into black and white areas, respectively; however, for example, when particles with irregularities are observed by SEM, there is a tendency that the irregular parts on the particles become black and white, making it difficult to determine the boundaries of the particles. Therefore, it is necessary to conduct observations by TEM or STEM, which do not generate black-and-white irregularities. However, by TEM observation alone, it tends to be difficult to determine whether the particles aggregate into a single particle or just look like a single particle by overlapping each other. Thus, it is better to take SEM and STEM images at the same time and analyze both images to accurately capture the shape of the particles and more accurately measure the equivalent circle diameter.

Specifically, the STEM image is imported into arbitrary image analysis software such as that used in Examples, the area of particles is measured, the results are imported into calculation software, the data of overlapping particles are removed by comparison with the SEM image taken at the same time, and the diameter calculated from the area of the remaining particles is used as the equivalent circle diameter. After compiling the equivalent circle diameters of all particles, the particle diameter median value (that is, the particle diameter for which the cumulative number of particles (frequency) is exactly 50% from the smaller particle side) is determined from the particle size distribution. Then, those with a particle diameter of 50% or less of this particle diameter median value are defined as “fine particles” in the present invention, and the proportion of the number of fine particles relative to the total number of particles is determined as the number distribution ratio. For example, when the total number of particles is 500, the particle diameter for which the cumulative number of particles is 250 from the smaller particle side is the particle diameter median value, and when the particle diameter median value is, for example, 30 nm, particles with a particle diameter of half that value (15 nm) or less are considered to be “fine particles”. The number distribution ratio of such fine particles of 15 nm or less being 1% or less means that the number of fine particles is 5 or less, since the total number of particles is 500.

Also, the colloidal silica of the present invention may have arbitrary shapes and characteristics depending on the application, purpose, or other factors, as long as the fine particles are in the predetermined number distribution ratio as described above. In particular, the colloidal silica obtained in the present invention has many small irregular protrusions on its particle surface, as can be grasped from the drawings described below, and the particles as a whole have a shape similar to konpeito, so to speak. Thus, the colloidal silica has a large BET specific surface area despite its large SEM average particle diameter, which is determined by measuring the arithmetic mean of particle images observed by SEM, and also has the property of a high particle density (true specific gravity) as measured by the liquid phase displacement method, in other words, a high hardness, making it suitable for CMP abrasives due to its excellent polishing speed. For example, in the case of colloidal silica used in the field of abrasives for semiconductor wafers, the particle diameter median value based on the equivalent circle diameter by the electron microscope image analysis described above is preferably in the range of 5 to 500 nm, and more preferably 30 to 300 nm. Small particles are unlikely to occur when attempting to produce small particle diameter products.

Note that the shape of colloidal silica particles can be controlled depending on the compositional features to be charged and other factors, to be monodispersed and spherical (spherical products), or to have a shape in which the particles are joined and aggregated (aggregated products), for example. For example, by pouring a larger amount of the catalyst and the organosilicate as the silica raw material into the reaction field relatively slowly, the organosilicate is hydrolyzed promptly, uniformly, and grows mildly, allowing the seed particles to grow gradually while maintaining their spherical shape, resulting in spherical products. Also, for example, by pouring a smaller amount of the catalyst and the organosilicate as the silica raw material into the reaction field relatively promptly, the organosilicate is hydrolyzed non-uniformly, so that it behaves like an adhesive between the particles, resulting in aggregated products in which the particles are aggregated.

In addition, the viscosity of the colloidal silica of the present invention may be preferably 1 to 100 mPa·s, and more preferably 1 to 20 mPa·s. Also, the BET particle diameter (nm) of the colloidal silica may be preferably 10 nm to 500 nm, and more preferably 18 nm to 200 nm.

Also, as mentioned above, the colloidal silica of the present invention may be monodispersed spherical products, or may be aggregated products (cocoon-shaped, chain-shaped, or branched) with a shape that appears to be formed by multiple particles joining in two or three dimensions by electron microscopic observation.

Since the colloidal silica of the present invention has the characteristics as described above, it is suitable for applications such as abrasives (silicon wafers, hard disks, and others), coating agents (eyeglasses, displays, building materials, paper, and others), and binders (ceramics, catalysts, and others), for example.

### <Method for Producing Colloidal Silica>

As described above, the colloidal silica of the present invention is obtained by feeding an easily hydrolyzable organosilicate to a reaction solution containing a hydrolysis catalyst composed of one or a mixture of two or more selected from organic amines, and allowing it to undergo a hydrolysis reaction.

First, as described above, in the production method of the present invention, it is important to prevent the easily hydrolyzable organosilicate, which is the silica source (hereinafter, this may be simply referred to as “silica source”), from scattering at the time of feeding, to prevent scattering to the surroundings such as walls in the reaction vessel and the occurrence of side reactions, and to prevent production of fine particles. Although the production of fine particles is as described above and the principle is not necessarily clear, it is assumed that when the scattering silica source scatters to the surroundings such as the walls of the reaction vessel, colloidal silica particulates are produced through contact and side reactions with water droplets adhering to surrounding walls and other surfaces, and when such side reaction products fall into the reaction solution along with water droplets, they cause production of colloidal silica fine particles that have undergone particle growth with behavior different from that of the normally targeted reaction.

Therefore, in the production method of the present invention, the silica source is fed with the feeding port for feeding the silica source to the reaction solution immersed under the surface of the reaction solution. By immersing the feeding port under the surface of the reaction solution and feeding (discharging) the silica source in the reaction solution as described above, scattering of the silica source at the feeding port and the surface of the reaction solution can be prevented as much as possible, compared to aerial pouring. At that time, for the degree of immersion of the feeding port, it is suitable to immerse it for a sufficient length such that the silica source fed (discharged) from the feeding port does not jump out of the surface of the reaction solution, and preferably, the length of the immersed feeding port may be three or more times the outer diameter of the feeding port (the outer pipe outer diameter when a nozzle with the double pipe structure described later is used). The upper limit of the length of the immersed feeding port can be determined in consideration of contact with other facilities (for example, the stirrer, the walls and bottom of the reaction vessel, and the like) and other factors, and may be preferably a length that is not in contact with the bottom of the inside of the reaction vessel. Note that, for the feeding port, those with any known shapes and dimensions may be used without any restrictions as long as they do not harm the object of the present invention, but it may be a nozzle or pipe with the discharging section in a circular, rectangular, or other shape, as is normally used. The outer diameter of the feeding port is not restricted, but it can be normally about 1 mm to 100 mm. Also, as for the reaction vessel in which the reaction is performed, those with any known shapes and dimensions can be used without any restrictions.

In order to sufficiently allow the silica source fed from the feeding port to undergo a hydrolysis reaction with the reaction solution in the reaction vessel or the like, it is preferable to provide sufficient stirring power to stir the reaction solution, and it may be preferable to provide power per unit liter of the solution to be stirred (unit: watts (W)/L) of 0.05 to 0.5 W/L, and more preferably 0.09 to 0.2 W/L.

In addition, when the silica source is fed (discharged) with the feeding port immersed in the reaction solution, it is preferable to accompany a means of promoting or assisting the feeding (discharging) of the silica source. Examples of such a means include the use of an inert gas or the use of a neutral gas that does not react with the silica source, water, or catalyst, but more preferably, the feeding (discharging) of the silica source into the reaction solution may be promoted or assisted with the inert gas by installing a feeding port for feeding the inert gas alongside or separately from the feeding port for the silica source. Inert gases such as nitrogen, argon, and helium can be used as appropriate depending on the purpose. Accompanying such a means is preferable since it allows the hydrolysis reaction to proceed sufficiently without problems such as stagnation of the fed silica source near the feeding port or clogging due to side reactions.

When the inert gas is used, the amount of the inert gas fed is preferably set in consideration of the degree to which the feeding of the silica source into the reaction solution is promoted or assisted, and so as to suppress as much as possible any blowout or the like of the silica source from the solution due to excessive gas flow rate. For example, the gas volume (L) per unit mass (kg) of the silica source to be fed is preferably 1 to 10,000 L/kg, and more preferably 10 to 1,000 L/kg.

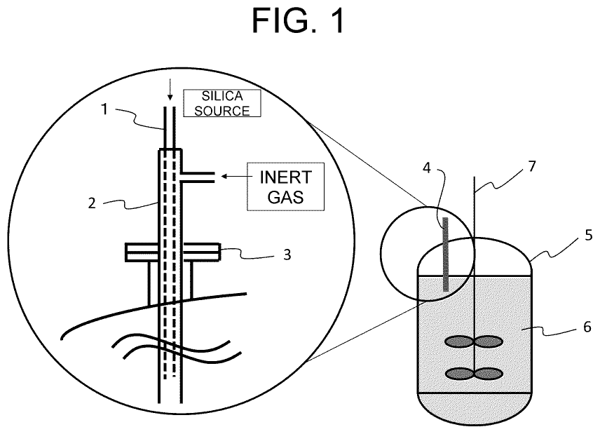

In order to feed the silica source to the reaction solution more reliably, using a nozzle having an inner/outer double pipe structure with an outer pipe and an inner pipe inserted into the outer pipe as the means of feeding the silica source, and feeding the silica source or inert gas from each pipe is a suitable embodiment in terms of reliability and efficiency of the feeding. In this case, it is preferable to allow the silica source to flow through the inner pipe and the inert gas to flow through the outer pipe in order to suppress scattering or the like of the silica source from the feeding port. For such a double pipe structure, for example, the form illustrated in FIG. 1 can be used, but any known nozzle having a double pipe structure can be used without any restrictions. Note that, in this case, it does not matter if there are multiple pipe lines, as long as there are at least double pipes that feed the silica source and the inert gas.

As for the diameters of the pipes through which the respective substances flow using such a nozzle having a double pipe structure, it is suitable that the ratio of the inner diameter (O) of the outer pipe feeding the inert gas relative to the outer diameter (I) of the inner pipe feeding the silica source, O/I, is 1 to 10. More preferably, the O/I may be 2 to 7. By setting the O/I ratio as such, the effect and efficiency of feeding the inert gas from the outer pipe is improved, thereby suppressing stagnation, clogging and so on of the silica source near the feeding port, which tends to realize more reliable feeding of the silica source.

The inner diameters of the respective pipes can be set as appropriate depending on the scale, amount fed, flow rate, and other factors during production, but the outer diameter (I) of the inner pipe feeding the silica source may be normally 5 to 96 mm, and more preferably 4 to 99 mm. As for the inner diameter (0) of the outer pipe feeding the inert gas, it may be normally 4 to 99 mm, and may be more preferably 6 to 98 mm.

Furthermore, in such an embodiment, the length of the outer pipe through which the inert gas flows is preferably larger than the length of the inner pipe through which the silica source flows. This is because the effect and efficiency of feeding the inert gas from the outer pipe is improved, thereby suppressing stagnation and clogging of the silica source near the feeding port, which tends to realize more reliable feeding of the silica source. Preferably, the difference in length between the inner pipe feeding the silica source and the outer pipe feeding the inert gas (length of outer pipe-length of inner pipe) may be the outer diameter of the outer pipe or more, and may be 0.5 or more times and 20 or less times the outer diameter of the outer pipe, and may be more preferably 1 or more times and 10 or less times the outer diameter of the outer pipe. The difference in length can be determined from the difference in length near the feeding ports of the two, as shown in FIG. 1.

Here, the silica source used in the present invention is an easily hydrolyzable organosilicate with a high hydrolysis rate, and the easily hydrolyzable organosilicate refers to one in which 10 g of the organosilicate and 100 g of pure water with 0.1 ppb or less of impurities are allowed to undergo a hydrolysis reaction at 25° C. under stirring, and this hydrolysis reaction is completed within 1 hour. Specific examples of such an easily hydrolyzable organosilicate include trimethyl silicate (hydrolysis reaction time until the hydrolysis reaction is completed: 3 minutes), tetramethyl silicate (hydrolysis reaction time: 5 minutes), triethyl silicate (hydrolysis reaction time: 5 minutes), and methyl trimethyl silicate (hydrolysis reaction time: 7 minutes). Tetraethyl silicate and organosilicates with a larger number of carbon atoms are not suited as the organosilicate to be used in the present inventive method because of their low hydrolysis rate and easy gelation (hydrolysis reaction time: 24 hours or more for all of them).

Also, in the present invention, although the organic amines used as the hydrolysis catalyst are not restricted, one or a mixture of two or more selected from quaternary ammoniums, tertiary amines, secondary amines, and primary amines, as well as carbonates, bicarbonates, and silicates thereof, can be widely used. Here, examples of the quaternary ammoniums include quaternary ammoniums such as tetramethylammonium hydroxide (TMAH), tetraethylammonium hydroxide (TEAH), trimethylethylammonium hydroxide, trimethylethanolammonium hydroxide (choline), triethylethanolammonium hydroxide, tetrapropylammonium hydroxide, and butylammonium hydroxide, as well as carbonates, bicarbonates, and silicates thereof. Since a relatively high pH is desirable for the hydrolysis reaction, tetramethylammonium hydroxide (TMAH), choline, or tetraethylammonium hydroxide (TEAH) is preferable.

Also, the primary amines, secondary amines, and tertiary amines of the organic amines used as the hydrolysis catalyst are not restricted, but examples thereof include aminoalcohols, morpholines, piperazines, aliphatic amines, and aliphatic etheramines. Here, a variety of aminoalcohols, including ethanolamine derivatives, can be used as the aminoalcohols, but ethanolamine derivatives are suitable, and examples thereof include monoethanolamine, diethanolamine, triethanolamine, N,N-dimethylethanolamine, N,N-diethylethanolamine, N,N-di-n-butylethanolamine, N-(β-aminoethyl) ethanolamine, N-methylethanolamine, N-methyldiethanolamine, N-ethylethanolamine, N-n-butylethanolamine, N-n-butyldiethanolamine, N-tert-butylethanolamine, and N-tert-butyldiethanolamine.

Furthermore, as for the morpholines of the organic amines used as the hydrolysis catalyst, a variety of morpholine derivatives can be used, but examples thereof preferably include morpholine, N-methylmorpholine, and N-ethylmorpholine. Moreover, as for the piperazines of the organic amines used as the hydrolysis catalyst, a variety of piperazine derivatives can be used, but examples thereof preferably include piperazine and hydroxyethylpiperazine. Also, as for the aliphatic amines and aliphatic etheramines of the organic amines used as the hydrolysis catalyst, suitable examples of the aliphatic amines include alkylamines having 1 to 8 carbon atoms such as triethylamine, dipropylamine, pentylamine, hexylamine, heptylamine, and octylamine, and suitable examples of the aliphatic etheramines include aliphatic etheramines having 1 to 8 carbon atoms such as 2-methoxyethylamine, 3-methoxypropylamine, 3-ethoxypropylamine, 3-propoxypropylamine, 3-isopropoxypropylamine, and 3-butoxypropylamine.

As for these organic amines used as the hydrolysis catalyst, only one of them can be used alone, or if necessary, two or more of them can be used as a mixture.

The reaction solution in the present invention, as described above, essentially contains the silica source and hydrolysis catalyst, but other than these, water, alcohols, aldehydes, ketones, surfactants, and other materials can be used. Preferably, the reaction solution contains 90% by mass or more of the silica source, hydrolysis catalyst, and water in total. More preferably, they are 95% by mass or more.

In the present invention, in the mixture after the reaction between the silica source and the hydrolysis catalyst described above (hereinafter, this may be referred to as “reaction mixture”), or in the reaction mixture that has been subsequently subjected to alcohol removal or dispersion stabilization treatment with an acid as will be described later (hereinafter, this may be particularly referred to as “reaction concentrate”), the hydrolysis catalyst may be added into the reaction system to perform the hydrolysis reaction such that the proportion of the hydrolysis catalyst (A) to silica (B) {residual catalyst molar ratio (A/B)} is preferably 0.012 or less, more preferably in the range of 0.00035 to 0.012, and still more preferably in the range of 0.0035 to 0.011. By doing so, the pH of the above reaction mixture or reaction concentrate can be optimized, and thickening or gelation can be suppressed, which is preferable.

There are no particular restrictions on the method of achieving such a residual catalyst molar ratio, but examples thereof include the following: a method of continuously or intermittently introducing the silica source calculated such that the final residual catalyst molar ratio (A/B) is within the aforementioned range, into a reaction vessel in which water and the hydrolysis catalyst (A) have been charged; a method of continuously or intermittently introducing the hydrolysis catalyst and silica source calculated such that the final residual catalyst molar ratio is within the range described above, into a reaction vessel in which only water has been charged; a method of continuously or intermittently introducing the hydrolysis catalyst and silica source calculated such that the final residual catalyst molar ratio is within the range described above, into a reaction vessel in which water and a small amount of the hydrolysis catalyst (A) have been charged.

Also, in the reaction system of the hydrolysis reaction, colloidal silica seeds with particle growth performance may be charged prior to the hydrolysis reaction of the silica source, and the silica source and hydrolysis catalyst may be gradually added into this reaction system such that the residual catalyst molar ratio (A/B) is within the above-mentioned range, which is preferable since this enables production of uniform particles of colloidal silica.

Furthermore, in the present invention, it is preferable that the silica source, hydrolysis catalyst, and water used as raw materials for the hydrolysis reaction have a metallic impurity content of 1 ppm or less, and more preferably, those with high purity of 0.01 ppm or less are used, thereby easily producing a high purity colloidal silica dispersion with a low metallic impurity content, which is preferable. That is, the colloidal silica dispersion to be obtained also preferably satisfies the said range of the metallic impurity content, and still more preferably, the metallic impurity content is 0.0001 ppm or less.

Here, in the present invention, it is preferable to remove the alcohol produced from the hydrolyzable organosilicate after the reaction between the easily hydrolyzable organosilicate and the hydrolysis catalyst. There are no particular restrictions on the method of such an alcohol removal treatment, but for example, examples thereof include a method in which the alcohol is distilled out by heating using equipment fitted with a condenser-attached distillation pipe. By performing such an alcohol removal treatment, the alcohol tolerance of materials used in subsequent steps does not need to be considered, and the concentration of colloidal silica is stabilized because of the elimination of the highly volatile alcohol, which is preferable.

Next, the reaction mixture after performing the alcohol removal treatment as described above is preferably subjected to dispersion stabilization with an acid. As such a dispersion stabilization treatment, a carbon dioxide gas blowing method in which carbon dioxide gas is blown, or an acid solution adding method in which an acid solution is added under stirring are performed. Either the carbon dioxide gas blowing method or the acid solution adding method may be performed, or both of these methods may be used in combination, but in any case, it is necessary to maintain the reaction mixture in a stirred state by operations such as bubbling with carbon dioxide gas and stirring during the dispersion stabilization treatment.

In the case where the dispersion stabilization treatment is performed by the carbon dioxide gas blowing method, the carbon dioxide gas blown into the reaction mixture may be 100% by volume of carbon dioxide gas, may be inert gas-diluted carbon dioxide gas that has been diluted to about 0.1% by volume with an inert gas such as nitrogen gas, or may even be air, but preferably, it may be 100% by volume of carbon dioxide gas or 1% by volume or more of inert gas-diluted carbon dioxide gas.

Then, as for the treatment conditions during this carbon dioxide gas blowing method, since the carbon dioxide gas blowing itself has a stirring effect, the carbon dioxide gas may be introduced into the reaction mixture under stirring normally at 0 rpm or more and 3,000 rpm or less, preferably 0 rpm or more and 1,000 rpm or less, at a temperature of higher than 0° C. and lower than 100° C., preferably 5° C. or higher and 80° C. or lower, and at a rate of preferably greater than 0 mL/min and 100,000 mL/min or less, more preferably 1 mL/min or more and 10,000 mL/min or less.

Also, in the case where the dispersion stabilization treatment is performed by the acid solution adding method, it is preferable to use an acid aqueous solution with a concentration of 20% by weight or less as the acid solution to be used, and it is one or a mixture of two or more selected from carbonic acid aqueous solutions, dilute mineral acid aqueous solutions with a concentration of 20% by weight or less, and dilute organic acid aqueous solutions with a concentration of 20% by weight or less, and preferably one or a mixture of two or more selected from dilute mineral acid aqueous solutions with a concentration of 10% by weight or less and dilute organic acid aqueous solutions with a concentration of 10% by weight or less. Specific examples thereof include inorganic acids such as hydrochloric acid, sulfuric acid, nitric acid, hydrofluoric acid, boric acid, carbonic acid, hypophosphorous acid, phosphorous acid, and phosphoric acid, and organic acids such as formic acid, acetic acid, propionic acid, butyric acid, valeric acid, 2-methylbutyric acid, n-hexanoic acid, 3,3-dimethylbutyric acid, 2-ethylbutyric acid, 4-methylpentanoic acid, n-heptanoic acid, 2-methylhexanoic acid, n-octanoic acid, 2-ethylhexanoic acid, benzoic acid, glycolic acid, salicylic acid, glyceric acid, oxalic acid, malonic acid, succinic acid, glutaric acid, adipic acid, pimelic acid, maleic acid, phthalic acid, malic acid, tartaric acid, citric acid, lactic acid, diglycolic acid, 2-furancarboxylic acid, 2,5-furandicarboxylic acid, 3-furancarboxylic acid, 2-tetrahydrofurancarboxylic acid, methoxyacetic acid, methoxyphenylacetic acid, phenoxyacetic acid, methanesulfonic acid, ethanesulfonic acid, and isethionic acid. The acid solution to be used is selected as appropriate depending on the application and other factors.

As for the treatment conditions during the acid aqueous solution adding method, the acid solution may be added under stirring normally at 1 rpm or more and 3,000 rpm or less, preferably 10 rpm or more and 1,000 rpm or less, at a temperature of normally 0° C. or higher and 100° C. or lower, preferably 5° C. or higher and 80° C. or lower, and in the range of normally 0.0001 moles or more and 10 moles or less, preferably 0.001 moles or more and 1 mole or less, as acid per 1 mole of catalyst in the reaction mixture to be treated.

The reaction mixture (reaction concentrate) that has undergone the dispersion stabilization treatment by the method of the present invention has a silica concentration of 10% by mass or more and 40% by mass or less and a pH value of pH 6.0 or more and 8.1 or less, and can almost maintain its pH value before the dispersion stabilization treatment, and also exhibits excellent dispersion stability normally for several weeks or even for several years, and no two-layer separation phenomenon occurs.

In the present invention, a colloidal silica with reduced fine particles can be obtained as described above, but depending on the application and so on, the obtained colloidal silica can be used as seed particles, and a silica source is fed to and allowed to react with a reaction solution containing the seed particles and the hydrolysis catalyst to produce a grown colloidal silica with a grown particle diameter. In particular, when trying to obtain a colloidal silica with a particle diameter median value of larger than 30 nm, the proportion of fine particles tends to be significantly increased by the conventional method. Therefore, by using, as seed particles, a colloidal silica obtained using the means of in-liquid feeding (discharging) of the silica source as described above and allowing it to undergo particle growth, a colloidal silica with reduced fine particles and a relatively large particle diameter can be obtained.

For the grown colloidal silica that is to undergo particle growth, it can be set and implemented as appropriate to achieve that particle diameter depending on the application and purpose. For example, as described above, it is suitable to use seed particles of colloidal silica with a particle diameter median value based on the equivalent circle diameter by image analysis using an electron microscope of 30 nm or less to produce a grown colloidal silica in which the particle diameter median value is greater than 30 nm. There are no restrictions on the particle diameter after growth, but it is preferably a particle diameter of about 1 mm, which can be stirred with stirring force that does not cause the particles to settle and that does not cause mist to fly at the time of stirring.

When performing particle growth, it is preferable to perform the reaction such that the silica concentration is 13% by mass or less, because when the temperature of the reaction solution is high, a higher silica concentration in the reaction system tends to cause boiling of the alcohol generated at the time of hydrolysis. The silica concentration here follows the definition described in Examples.

### EXAMPLES

Hereinafter, suitable embodiments of the present invention will be specifically described based on Examples and Comparative Examples.

### Example 1

In a 1000 liter (L) stainless steel reaction vessel equipped with a stirrer, a temperature sensor, heating steam piping, cooling water piping, exhaust gas piping, and a double pipe organosilicate introduction pipe having the structure illustrated in FIG. 1, 542.58 kg of pure water with a metallic impurity content of 0.1 ppb or less and 0.58 kg of triethanolamine (bp: 361° C.) with a metallic impurity content of 10 ppb or less were charged. The double pipe had an outer diameter of 25.4 mm, an inner diameter of 22 mm, and an in-kettle length of 723 mm for the outer pipe, and an outer diameter of 6.35 mm, an inner diameter of 3.5 mm, and an in-kettle length of 553 mm for the inner pipe. At that time, the double pipe organosilicate introduction pipe was confirmed to have an immersion length of 20 cm from the liquid surface into the liquid under stirring.

After confirmation, while keeping the liquid temperature in the reaction vessel at 80° C. using steam and cooling water, 236.84 kg of tetramethyl silicate (silica source; manufactured by Tama Chemicals Co., Ltd.) with a metallic impurity content of 10 ppb or less and nitrogen at 0.5 L/min were allowed to flow on the inner pipe side and on the outer pipe side of the double pipe, respectively, and were continuously fed over 6 hours under stirring. During that time, the feeding ultimate pressure of the silica source remained unchanged at 0 MPa. When the nozzle was checked after the completion of the reaction, it was not clogged with silica.

Thereafter, the temperature in the reaction vessel was lowered to 40° C. to obtain a post-reaction product. Also, this post-reaction product was transferred to a 500 L stainless steel distillation vessel and a 500 L stainless steel intermediate vessel equipped with a stirrer, a temperature sensor, a pressure sensor, a liquid surface control sensor, heating steam piping, cooling water piping, and an 800 L stainless steel condenser with a distillate receiver connected to the exhaust gas piping, and sampled along the way for analysis of solid content. Thereafter, the system was depressurized to −73 kPa by a vacuum pump and then heated, and the evaporated gas was cooled with the condenser and distilled off into the distillate receiver. Each time the liquid in the distillation vessel was decreased, the reaction crude product was fed from the intermediate tank, and after the reaction crude product was depleted from the intermediate tank, 125.2 kg of pure water was fed to replace the solvent with water to obtain concentrated 20% colloidal silica.

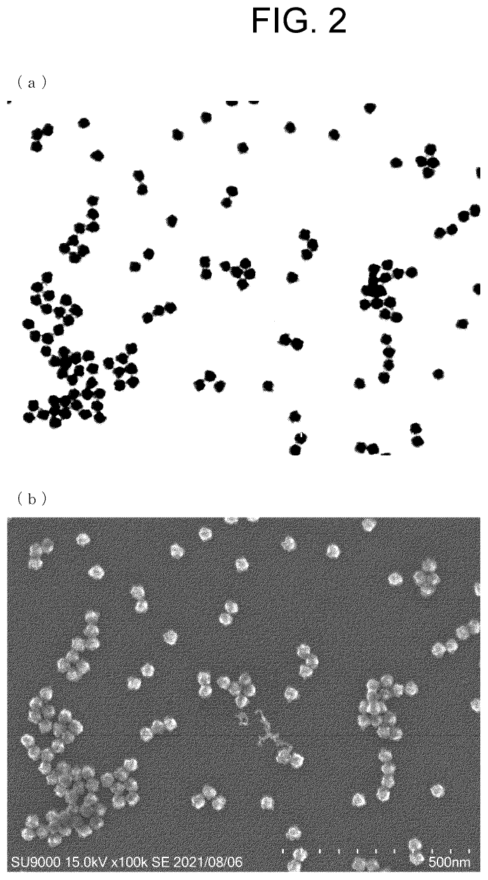

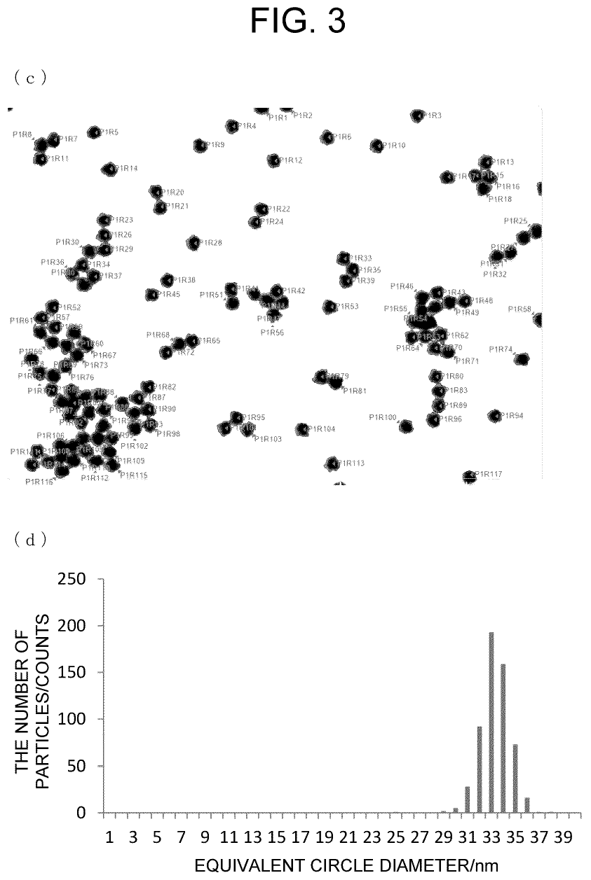

After blowing carbon dioxide gas into this concentrated product for 10 minutes at 1.2 L/min to perform the dispersion stabilization treatment, it was confirmed to be spherical particles with a uniform particle diameter and protrusions by electron microscopic observation, as shown in FIGS. 2 to 3. The equivalent circle diameter was measured by image analysis according to the procedure described later, and the particle diameter median value was determined from the particle size distribution and the number distribution ratio of fine particles was calculated. The results are shown in Table 1. Also, the metallic impurity content was 0.1 ppb or less.

### Example 2

In the same apparatus as in Example 1, 542.57 kg of pure water with a metallic impurity content of 0.1 ppb or less and 0.58 kg of triethanolamine (bp: 361° C.) with a metallic impurity content of 10 ppb or less were charged. At that time, the double pipe organosilicate introduction pipe was confirmed to have an immersion length of 20 cm from the liquid surface into the liquid under stirring. After confirmation, while keeping the liquid temperature in the reaction vessel at 70° C. using steam and cooling water, 236.85 kg of tetramethyl silicate (silica source; manufactured by Tama Chemicals Co., Ltd.) with a metallic impurity content of 10 ppb or less and nitrogen at 0.5 L/min were allowed to flow on the inner pipe side and on the outer pipe side of the double pipe, respectively, and were continuously fed over 6 hours under stirring. During that time, the feeding ultimate pressure of the silica source remained unchanged at 0 MPa. When the nozzle was checked after the completion of the reaction, it was not clogged with silica.

Thereafter, the temperature in the reaction vessel was lowered to 40° C., and 22.68 kg of this post-reaction product as seed particles, 526.17 kg of pure water with a metallic impurity content of 0.1 ppb or less, and 1.40 kg of triethanolamine (bp: 361° C.) with a metallic impurity content of 10 ppb or less were charged. At that time, the double pipe organosilicate introduction pipe was confirmed to have an immersion length of 20 cm from the liquid surface into the liquid under stirring.

After confirmation, while keeping the liquid temperature in the reaction vessel at 80° C. using steam and cooling water, 229.75 kg of tetramethyl silicate (silica source; manufactured by Tama Chemicals Co., Ltd.) with a metallic impurity content of 10 ppb or less and nitrogen at 0.5 L/min were allowed to flow on the inner pipe side and on the outer pipe side of the double pipe, respectively, and were continuously fed over 6 hours under stirring. Similarly, the feeding ultimate pressure of the silica source remained unchanged at 0 MPa, and the nozzle was not clogged after the completion of the reaction, either.

Thereafter, the temperature in the reaction vessel was lowered to 40° C., and the product was transferred to a 500 L stainless steel distillation vessel and a 500 L stainless steel intermediate vessel equipped with a stirrer, a temperature sensor, a pressure sensor, a liquid surface control sensor, heating steam piping, cooling water piping, and an 800 L stainless steel condenser with a distillate receiver connected to the exhaust gas piping, and sampled along the way for analysis of solid content. Thereafter, the system was depressurized to −73 kPa by a vacuum pump and then heated, and the evaporated gas was cooled with the condenser and distilled off into the distillate receiver. Each time the liquid in the distillation vessel was decreased, the reaction crude product was fed from the intermediate tank, and after the reaction crude product was depleted from the intermediate tank, 125.2 kg of pure water was fed to replace the solvent with water to obtain concentrated 20% colloidal silica.

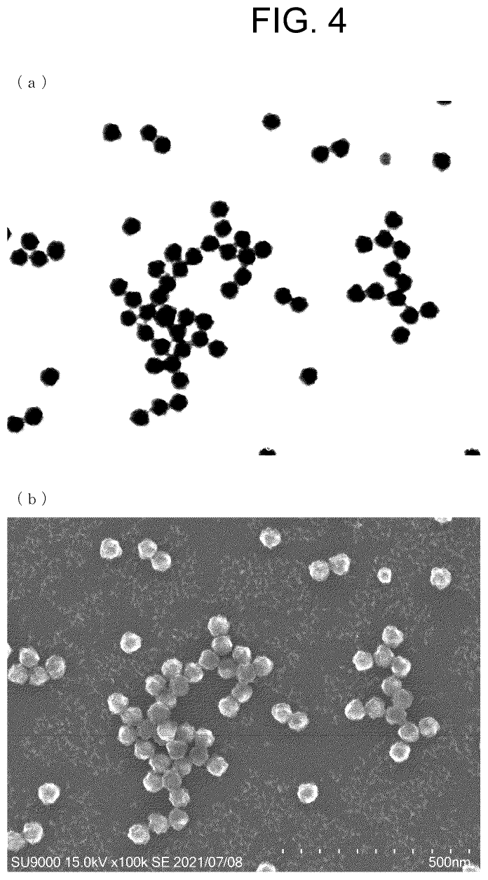

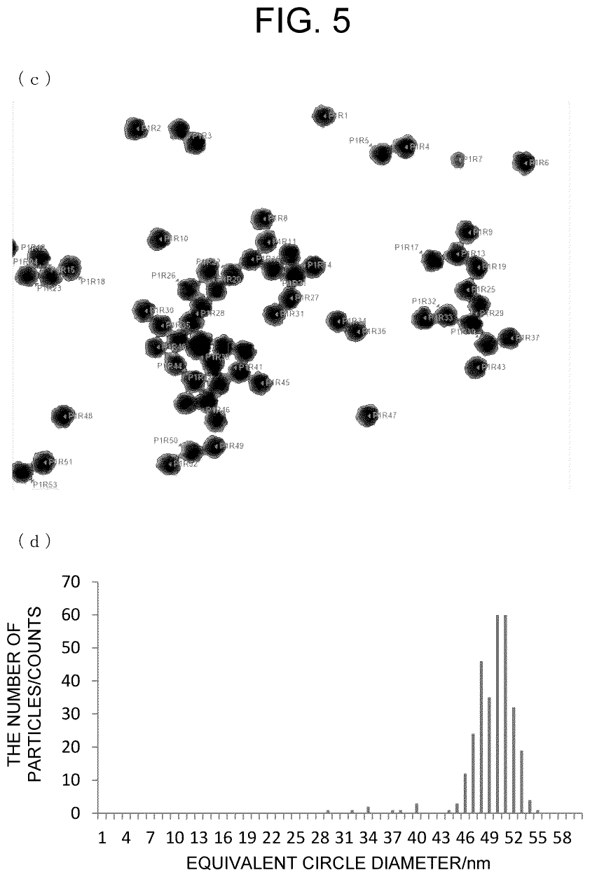

After blowing carbon dioxide gas into this concentrated product for 10 minutes at 1.2 L/min to perform the dispersion stabilization treatment, it was confirmed to be spherical particles with a uniform particle diameter and protrusions by electron microscopic observation, as shown in FIGS. 4 to 5. The equivalent circle diameter was measured by image analysis according to the procedure described later, and the particle diameter median value was determined from the particle size distribution and the number distribution ratio of fine particles was calculated. The results are shown in Table 1. Also, the metallic impurity content was 0.1 ppb or less.

### Example 3

In the same apparatus as in Example 1, 108.41 kg of the product obtained in Example 1 as seed particles, 467.71 kg of pure water with a metallic impurity content of 0.1 ppb or less, and 1.34 kg of triethanolamine (bp: 361° C.) with a metallic impurity content of 10 ppb or less were charged. At that time, the double pipe organosilicate introduction pipe was confirmed to have an immersion length of 20 cm from the liquid surface into the liquid under stirring.

After confirmation, while keeping the liquid temperature in the reaction vessel at 80° C. using steam and cooling water, 204.32 kg of tetramethyl silicate (silica source; manufactured by Tama Chemicals Co., Ltd.) with a metallic impurity content of 10 ppb or less and nitrogen at 0.5 L/min were allowed to flow on the inner pipe side and on the outer pipe side of the double pipe, respectively, and were continuously fed over 6 hours under stirring. During that time, the feeding ultimate pressure of the silica source remained unchanged at 0 MPa. When the nozzle was checked after the completion of the reaction, it was not clogged with silica.

Thereafter, the temperature in the reaction vessel was lowered to 40° C., and the product was transferred to a 500 L stainless steel distillation vessel and a 500 L stainless steel intermediate vessel equipped with a stirrer, a temperature sensor, a pressure sensor, a liquid surface control sensor, heating steam piping, cooling water piping, and an 800 L stainless steel condenser with a distillate receiver connected to the exhaust gas piping, and sampled along the way for analysis of solid content. Thereafter, the system was depressurized to −73 kPa by a vacuum pump and then heated, and the evaporated gas was cooled with the condenser and distilled off into the distillate receiver. Each time the liquid in the distillation vessel was decreased, the reaction crude product was fed from the intermediate tank, and after the reaction crude product was depleted from the intermediate tank, 125.2 kg of pure water was fed to replace the solvent with water to obtain concentrated 20% colloidal silica.

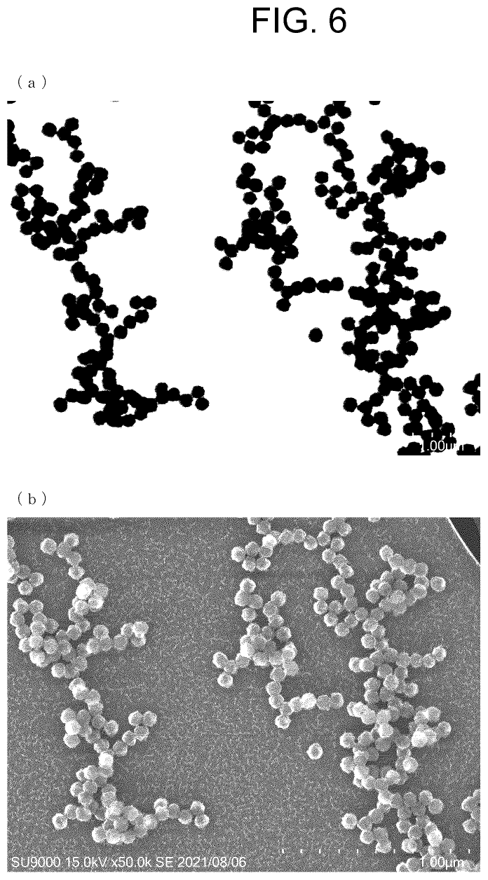

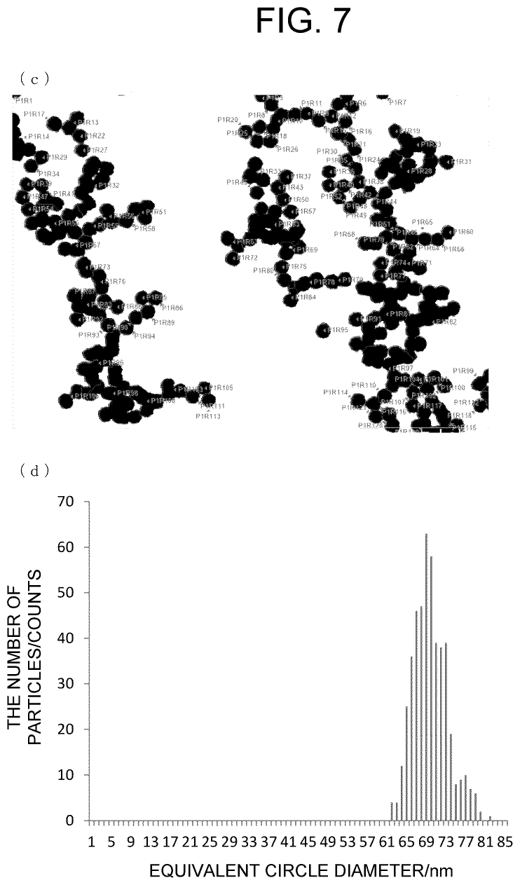

After blowing carbon dioxide gas into this concentrated product for 10 minutes at 1.2 L/min to perform the dispersion stabilization treatment, it was confirmed to be spherical particles with a uniform particle diameter and protrusions by electron microscopic observation, as shown in FIGS. 6 to 7. The equivalent circle diameter was measured by image analysis according to the procedure described later, and the particle diameter median value was determined from the particle size distribution and the number distribution ratio of fine particles was calculated. The results are shown in Table 1. Also, the metallic impurity content was 0.1 ppb or less.

### Example 4

The reaction was performed in the same apparatus as in Example 2 and in the same manner as in Example 2, except that the same double pipe as in Example 2 was used and the nitrogen flow rate was set to 1 L/min. During the reaction, the feeding ultimate pressure of the silica source remained unchanged at 0 MPa and the reaction was able to continue until the end. When the nozzle was checked after the completion, it was not clogged with silica.

### Comparative Example 1

In the same apparatus as in Example 1, 542.58 kg of pure water with a metallic impurity content of 0.1 ppb or less and 0.58 kg of triethanolamine (bp: 361° C.) with a metallic impurity content of 10 ppb or less were charged, except that a single pipe introduction pipe feeding the organosilicate (silica source) was used instead of the double pipe used in Example 1. At that time, the single pipe organosilicate introduction pipe was confirmed to be at a height where it could not reach the liquid surface under stirring even if all of the organosilicate was poured in.

After confirmation, while keeping the liquid temperature in the reaction vessel at 80° C. using steam and cooling water, 236.84 kg of tetramethyl silicate (silica source; manufactured by Tama Chemicals Co., Ltd.) with a metallic impurity content of 10 ppb or less was allowed to flow in the single pipe, and was continuously fed over 6 hours under stirring. During that time, the feeding ultimate pressure of the silica source remained unchanged at 0 MPa. When the nozzle was checked after the completion of the reaction, it was not clogged with silica.

Thereafter, the temperature in the reaction vessel was lowered to 40° C. to obtain a post-reaction product. Also, this post-reaction product was transferred to a 500 L stainless steel distillation vessel and a 500 L stainless steel intermediate vessel equipped with a stirrer, a temperature sensor, a pressure sensor, a liquid surface control sensor, heating steam piping, cooling water piping, and an 800 L stainless steel condenser with a distillate receiver connected to the exhaust gas piping, and sampled along the way for analysis of solid content. Thereafter, the system was depressurized to −73 kPa by a vacuum pump and then heated, and the evaporated gas was cooled with the condenser and distilled off into the distillate receiver. Each time the liquid in the distillation vessel was decreased, the reaction crude product was fed from the intermediate tank, and after the reaction crude product was depleted from the intermediate tank, 125.2 kg of pure water was fed to replace the solvent with water to obtain concentrated 20% colloidal silica.

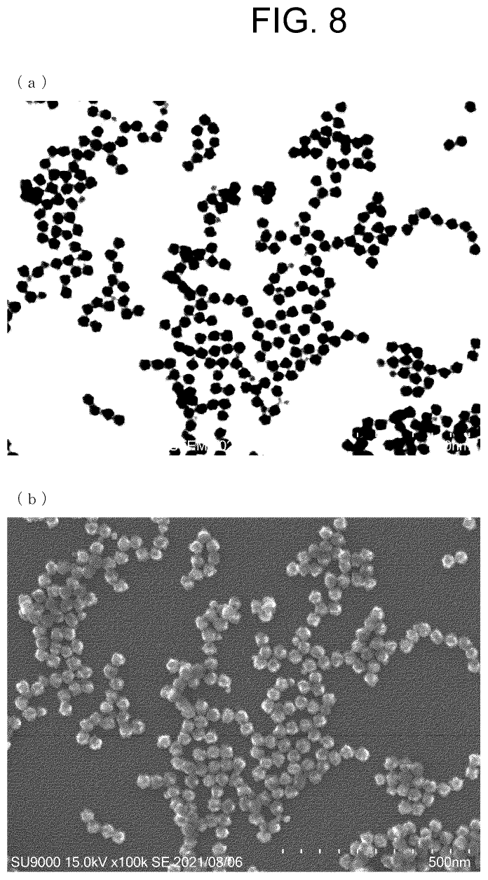

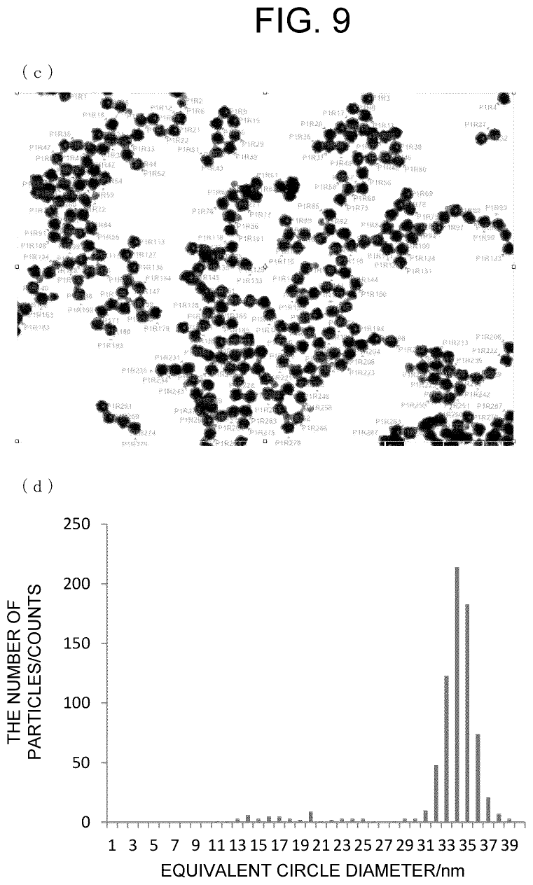

After blowing carbon dioxide gas into this concentrated product for 10 minutes at 1.2 L/min to perform the dispersion stabilization treatment, it was confirmed to be spherical particles with a non-uniform particle diameter and protrusions by electron microscopic observation, as shown in FIGS. 8 to 9. The equivalent circle diameter was measured by image analysis according to the procedure described later, and the particle diameter median value was determined from the particle size distribution and the number distribution ratio of fine particles was calculated. The results are shown in Table 1.

### Comparative Example 2

In the same apparatus as in Example 1, 542.57 kg of pure water with a metallic impurity content of 0.1 ppb or less and 0.58 kg of triethanolamine (bp: 361° C.) with a metallic impurity content of 10 ppb or less were charged, except that a single pipe introduction pipe feeding the organosilicate (silica source) was used instead of the double pipe used in Example 1. At that time, the single pipe organosilicate introduction pipe was confirmed to be at a height where it could not reach the liquid surface under stirring even if all of the organosilicate was poured in.

After confirmation, while keeping the liquid temperature in the reaction vessel at 70° C. using steam and cooling water, 236.85 kg of tetramethyl silicate (silica source; manufactured by Tama Chemicals Co., Ltd.) with a metallic impurity content of 10 ppb or less was continuously fed over 6 hours under stirring. During that time, the feeding ultimate pressure of the silica source remained unchanged at 0 MPa. When the nozzle was checked after the completion of the reaction, it was not clogged with silica.

Thereafter, the temperature in the reaction vessel was lowered to 40° C., and 22.68 kg of this post-reaction product as seed particles, 526.17 kg of pure water with a metallic impurity content of 0.1 ppb or less, and 1.40 kg of triethanolamine (bp: 361° C.) with a metallic impurity content of 10 ppb or less were charged. At that time, the single pipe organosilicate introduction pipe was confirmed to be at a height where it could not reach the liquid surface under stirring even if all of the organosilicate was poured in.

After confirmation, while keeping the liquid temperature in the reaction vessel at 80° C. using steam and cooling water, 229.75 kg of tetramethyl silicate (silica source; manufactured by Tama Chemicals Co., Ltd.) with a metallic impurity content of 10 ppb or less was continuously fed over 6 hours under stirring. During that time, the feeding ultimate pressure of the silica source remained unchanged at 0 MPa. When the nozzle was checked after the completion of the reaction, it was not clogged with silica.

Thereafter, the temperature in the reaction vessel was lowered to 40° C., and the product was transferred to a 500 L stainless steel distillation vessel and a 500 L stainless steel intermediate vessel equipped with a stirrer, a temperature sensor, a pressure sensor, a liquid surface control sensor, heating steam piping, cooling water piping, and an 800 L stainless steel condenser with a distillate receiver connected to the exhaust gas piping, and sampled along the way for analysis of solid content. Thereafter, the system was depressurized to −73 kPa by a vacuum pump and then heated, and the evaporated gas was cooled with the condenser and distilled off into the distillate receiver. Each time the liquid in the distillation vessel was decreased, the reaction crude product was fed from the intermediate tank, and after the reaction crude product was depleted from the intermediate tank, 125.2 kg of pure water was fed to replace the solvent with water to obtain concentrated 20% colloidal silica.

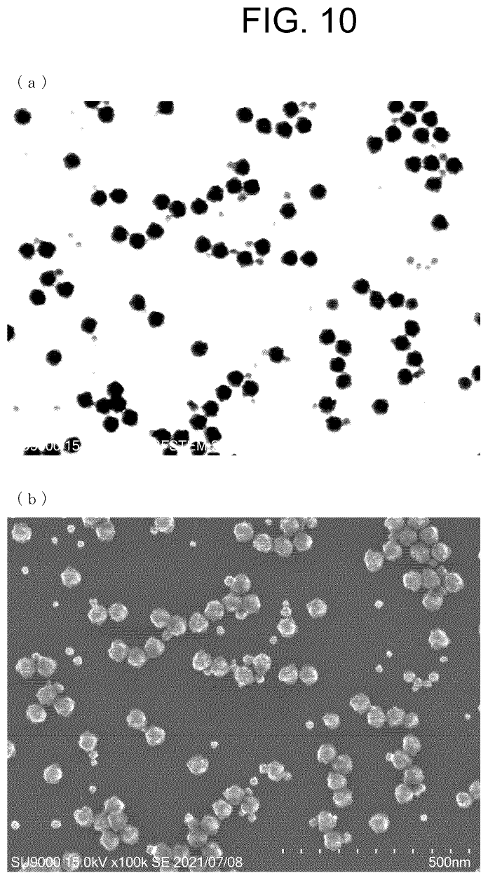

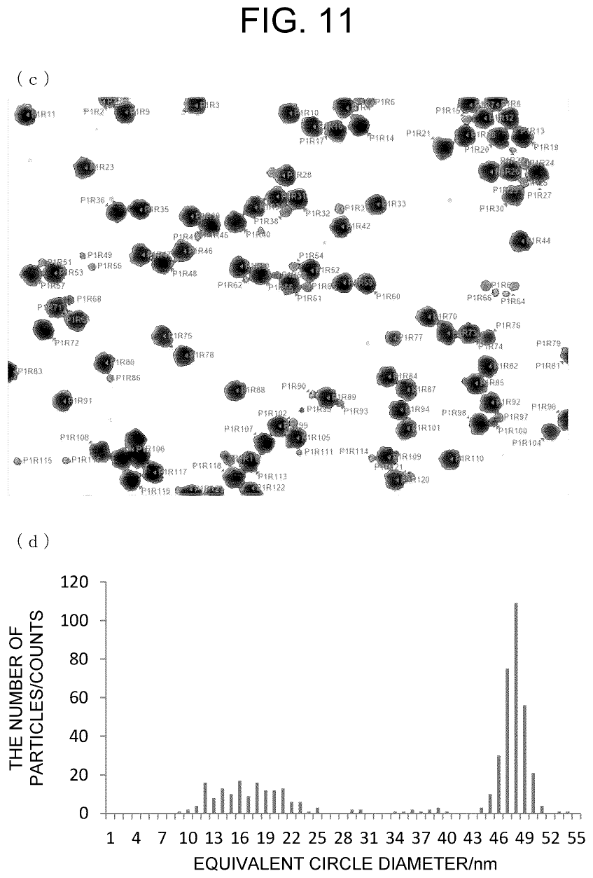

After blowing carbon dioxide gas into this concentrated product for 10 minutes at 1.2 L/min to perform the dispersion stabilization treatment, it was confirmed to be spherical particles with a non-uniform particle diameter and protrusions by electron microscopic observation, as shown in FIGS. 10 to 11. The equivalent circle diameter was measured by image analysis according to the procedure described later, and the particle diameter median value was determined from the particle size distribution and the number distribution ratio of fine particles was calculated. The results are shown in Table 1.

### Comparative Example 3

In the same apparatus as in Example 1, 108.41 kg of the product obtained in Comparative Example 1 as seeds, 467.71 kg of pure water with a metallic impurity content of 0.1 ppb or less, and 1.34 kg of triethanolamine (bp: 361° C.) with a metallic impurity content of 10 ppb or less were charged, except that a single pipe introduction pipe feeding the organosilicate (silica source) was used instead of the double pipe used in Example 1. At that time, the single pipe organosilicate introduction pipe was confirmed to be at a height where it could not reach the liquid surface under stirring even if all of the organosilicate was poured in.

After confirmation, while keeping the liquid temperature in the reaction vessel at 80° C. using steam and cooling water, 204.32 kg of tetramethyl silicate (silica source; manufactured by Tama Chemicals Co., Ltd.) with a metallic impurity content of 10 ppb or less was continuously fed over 6 hours under stirring. During that time, the feeding ultimate pressure of the silica source remained unchanged at 0 MPa. When the nozzle was checked after the completion of the reaction, it was not clogged with silica.

Thereafter, the temperature in the reaction vessel was lowered to 40° C., and the product was transferred to a 500 L stainless steel distillation vessel and a 500 L stainless steel intermediate vessel equipped with a stirrer, a temperature sensor, a pressure sensor, a liquid surface control sensor, heating steam piping, cooling water piping, and an 800 L stainless steel condenser with a distillate receiver connected to the exhaust gas piping, and sampled along the way for analysis of solid content. Thereafter, the system was depressurized to −73 kPa by a vacuum pump and then heated, and the evaporated gas was cooled with the condenser and distilled off into the distillate receiver. Each time the liquid in the distillation vessel was decreased, the reaction crude product was fed from the intermediate tank, and after the reaction crude product was depleted from the intermediate tank, 125.2 kg of pure water was fed to replace the solvent with water to obtain concentrated 20% colloidal silica.

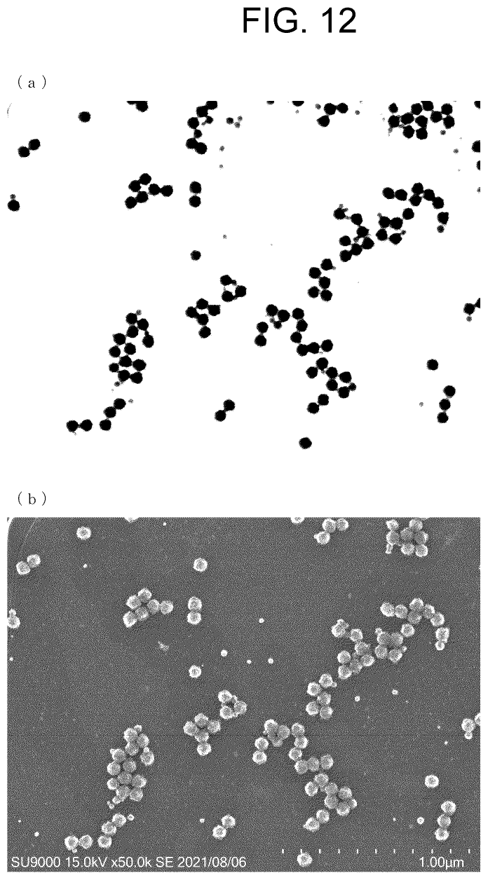

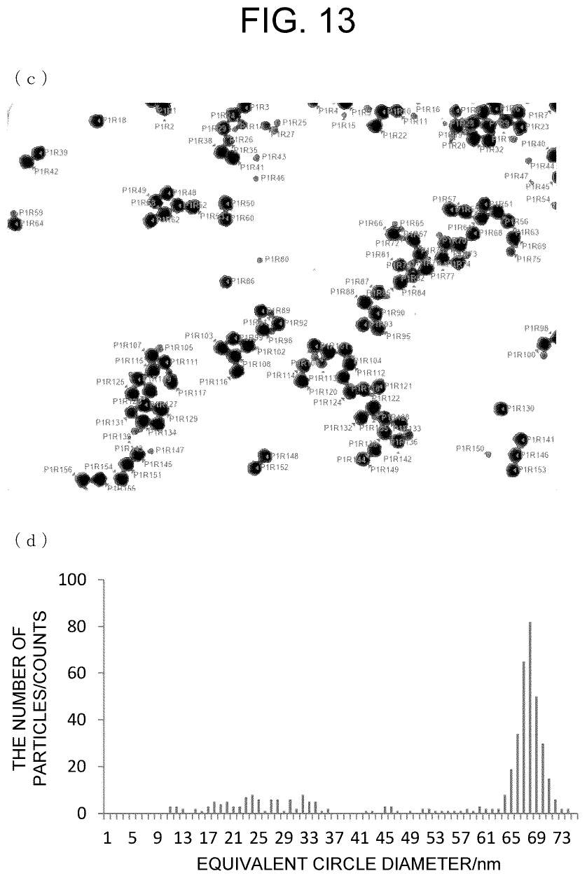

The reaction, distillation, and dispersion stabilization treatment were performed in the same apparatus as in Example 1, except that the apparatus was equipped with the organosilicate introduction pipe with a length that remained outside the liquid after the organosilicate had been introduced and nitrogen was not introduced, and electron microscopic observation confirmed that the particles were spherical with a non-uniform particle diameter and protrusions, as shown in FIGS. 12 to 13.

### Example 5

The reaction was performed in the same apparatus as in Example 2 and in the same manner as in Example 2, except that, for the double pipe of the apparatus of Example 2, the outer diameter, inner diameter, and in-kettle length on the inner pipe side were 6.35 mm, 3.5 mm, and 703 mm, respectively, the same solvent that is pure water, and catalyst as in Example 2 were charged, and the nitrogen flow rate was 4 L/min. During the reaction, the feeding ultimate pressure of the silica source changed to 0.08 MPa. When the nozzle was checked after the completion, clogging with silica was observed.

### Example 6

The reaction was performed in the same apparatus as in Example 2 and in the same manner as in Example 2, except that, for the double pipe of the apparatus of Example 2, the outer diameter, inner diameter, and in-kettle length on the outer pipe side were 12.7 mm, 10 mm, and 723 mm, respectively, the same solvent that is pure water, and catalyst as in Example 2 were charged, and the nitrogen flow rate was 4 L/min. During the reaction, the feeding ultimate pressure of the silica source changed to 0.08 MPa. When the nozzle was checked after the completion, clogging with silica was observed.

### Example 7

The reaction was performed with the same solvent that is pure water, and catalyst as in Example 2 charged, in the same apparatus as in Example 2 and with a nitrogen flow rate of 0.5 L/min in the same manner as in Example 2, except that, for the double pipe of the apparatus of Example 2, the outer diameter, inner diameter, and in-kettle length on the outer pipe side were 12.7 mm, 10 mm, and 723 mm, respectively, the outer diameter, inner diameter, and in-kettle length on the inner pipe side were 6.35 mm, 3.5 mm, and 703 mm, respectively. During the reaction, the feeding ultimate pressure of the silica source changed to 0.04 MPa, and when the nozzle was checked after the completion, clogging with silica was observed.

### Example 8

The reaction was performed with the same solvent that is pure water, and catalyst as in Example 2 charged, in the same apparatus as in Example 2 with a nitrogen flow rate of 1 L/min, except that, for the double pipe of the apparatus of Example 2, the outer diameter, inner diameter, and in-kettle length on the outer pipe side were 12.7 mm, 10 mm, and 723 mm, respectively, the outer diameter, inner diameter, and in-kettle length on the inner pipe side were 6.35 mm, 3.5 mm, and 703 mm, respectively. During the reaction, the feeding ultimate pressure of the silica source changed to 0.02 MPa. When the nozzle was checked after the completion, clogging with silica was observed.

### Example 9

The reaction was performed with same solvent that is pure water, and catalyst as in Example 2 charged, in the same apparatus as in Example 2 with a nitrogen flow rate of 4 L/min, except that, for the double pipe of the apparatus of Example 2, the outer diameter, inner diameter, and in-kettle length on the outer pipe side were 12.7 mm, 10 mm, and 723 mm, respectively, the outer diameter, inner diameter, and in-kettle length on the inner pipe side were 6.35 mm, 3.5 mm, and 703 mm, respectively. During the reaction, the feeding ultimate pressure of the silica source changed to 0.02 MPa. When the nozzle was checked after the completion, clogging with silica was observed.

### Example 10

In a 1000 liter (L) stainless steel reaction vessel equipped with a stirrer, a temperature sensor, heating steam piping, cooling water piping, exhaust gas piping, and a double pipe organosilicate introduction pipe having the structure illustrated in FIG. 1, 542.70 kg of pure water with a metallic impurity content of 0.1 ppb or less and 0.4015 kg of 3-ethoxypropylamine (bp: 137° C.) with a metallic impurity content of 10 ppb or less were charged. The double pipe had an outer diameter of 25.4 mm, an inner diameter of 22 mm, and an in-kettle length of 723 mm for the outer pipe, and an outer diameter of 6.35 mm, an inner diameter of 3.5 mm, and an in-kettle length of 553 mm for the inner pipe. At that time, the double pipe organosilicate introduction pipe was confirmed to have an immersion length of 20 cm from the liquid surface into the liquid under stirring.

After confirmation, while keeping the liquid temperature in the reaction vessel at 80° C. using steam and cooling water, 236.90 kg of tetramethyl silicate (silica source; manufactured by Tama Chemicals Co., Ltd.) with a metallic impurity content of 10 ppb or less and nitrogen at 0.5 L/min were allowed to flow on the inner pipe side and on the outer pipe side of the double pipe, respectively, and were continuously fed over 6 hours under stirring. During that time, the feeding ultimate pressure of the silica source remained unchanged at 0 MPa. When the nozzle was checked after the completion of the reaction, it was not clogged with silica.

Thereafter, the temperature in the reaction vessel was lowered to 40° C. to obtain a post-reaction product. Also, this post-reaction product was transferred to a 500 L stainless steel distillation vessel and a 500 L stainless steel intermediate vessel equipped with a stirrer, a temperature sensor, a pressure sensor, a liquid surface control sensor, heating steam piping, cooling water piping, and an 800 L stainless steel condenser with a distillate receiver connected to the exhaust gas piping, and sampled along the way for analysis of solid content. Thereafter, the system was heated, and the evaporated gas was cooled with the condenser and distilled off into the distillate receiver. Each time the liquid in the distillation vessel was decreased, the reaction crude product was fed from the intermediate tank, and after the reaction crude product was depleted from the intermediate tank, 125.2 kg of pure water was fed to replace the solvent with water to obtain concentrated 20% colloidal silica.

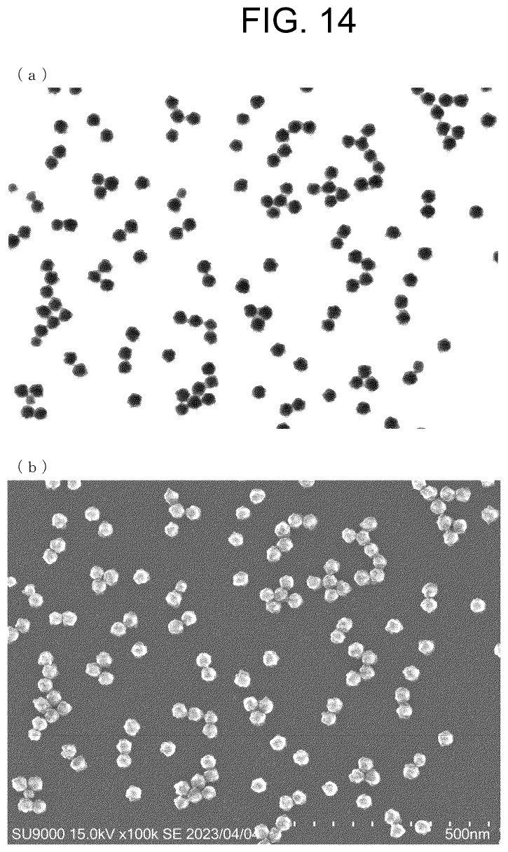

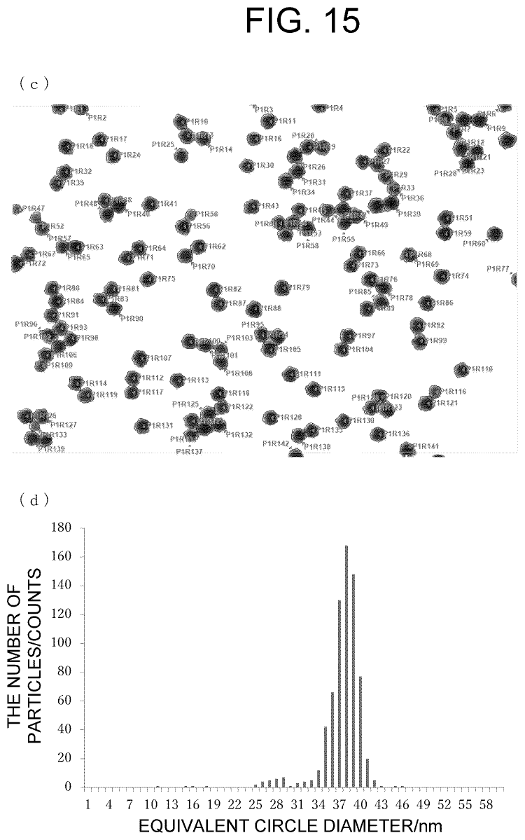

After blowing carbon dioxide gas into this concentrated product for 10 minutes at 1.2 L/min to perform the dispersion stabilization treatment, it was confirmed to be spherical particles with a uniform particle diameter and protrusions by electron microscopic observation, as shown in FIGS. 14 to 15. The equivalent circle diameter was measured by image analysis according to the procedure described later, and the particle diameter median value was determined from the particle size distribution and the number distribution ratio of fine particles was calculated. The results are shown in Table 1. Also, the metallic impurity content was 0.1 ppb or less.

### Comparative Example 4

In the same apparatus as in Example 1, 542.70 kg of pure water with a metallic impurity content of 0.1 ppb or less and 0.4015 kg of 3-ethoxypropylamine (bp: 137° C.) with a metallic impurity content of 10 ppb or less were charged, except that a single pipe introduction pipe feeding the organosilicate (silica source) was used instead of the double pipe used in Example 1. At that time, the single pipe organosilicate introduction pipe was confirmed to be at a height where it could not reach the liquid surface under stirring even if all of the organosilicate was poured in.

After confirmation, while keeping the liquid temperature in the reaction vessel at 70° C. using steam and cooling water, 236.9 kg of tetramethyl silicate (silica source; manufactured by Tama Chemicals Co., Ltd.) with a metallic impurity content of 10 ppb or less was continuously fed over 6 hours under stirring. During that time, the feeding ultimate pressure of the silica source remained unchanged at 0 MPa. When the nozzle was checked after the completion of the reaction, it was not clogged with silica.

Thereafter, the temperature in the reaction vessel was lowered to 40° C., and 103.24 kg of this post-reaction product as seed particles, 471.66 kg of pure water with a metallic impurity content of 0.1 ppb or less, and 0.929 kg of 3-ethoxypropylamine (bp: 137° C.) with a metallic impurity content of 10 ppb or less were charged. At that time, the single pipe organosilicate introduction pipe was confirmed to be at a height where it could not reach the liquid surface under stirring even if all of the organosilicate was poured in.

After confirmation, while keeping the liquid temperature in the reaction vessel at 80° C. using steam and cooling water, 204.18 kg of tetramethyl silicate (silica source; manufactured by Tama Chemicals Co., Ltd.) with a metallic impurity content of 10 ppb or less was continuously fed over 6 hours under stirring. During that time, the feeding ultimate pressure of the silica source remained unchanged at 0 MPa. When the nozzle was checked after the completion of the reaction, it was not clogged with silica.

Thereafter, the temperature in the reaction vessel was lowered to 40° C., and the product was transferred to a 500 L stainless steel distillation vessel and a 500 L stainless steel intermediate vessel equipped with a stirrer, a temperature sensor, a pressure sensor, a liquid surface control sensor, heating steam piping, cooling water piping, and an 800 L stainless steel condenser with a distillate receiver connected to the exhaust gas piping, and sampled along the way for analysis of solid content. Thereafter, the system was heated, and the evaporated gas was cooled with the condenser and distilled off into the distillate receiver. Each time the liquid in the distillation vessel was decreased, the reaction crude product was fed from the intermediate tank, and after the reaction crude product was depleted from the intermediate tank, 125.2 kg of pure water was fed to replace the solvent with water to obtain concentrated 20% colloidal silica.

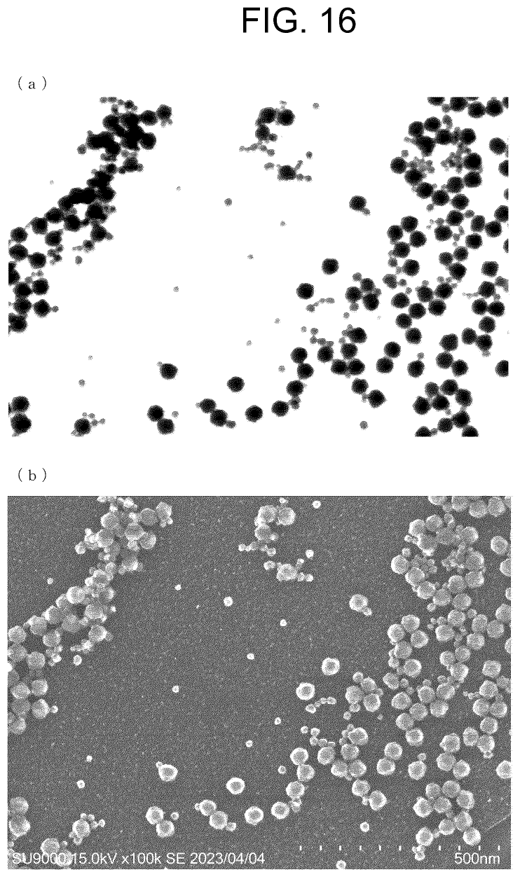

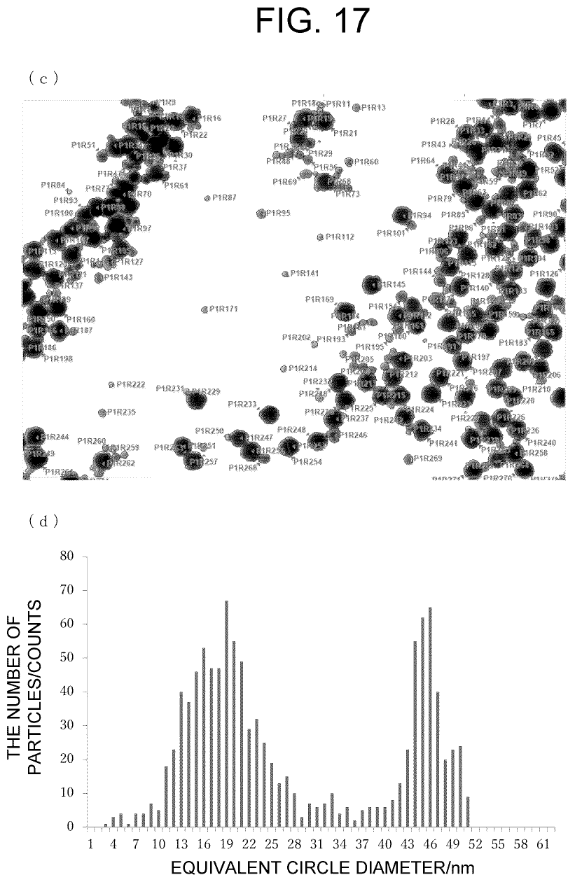

After blowing carbon dioxide gas into this concentrated product for 10 minutes at 1.2 L/min to perform the dispersion stabilization treatment, it was confirmed to be spherical particles with a non-uniform particle diameter and protrusions by electron microscopic observation, as shown in FIGS. 16 to 17. The equivalent circle diameter was measured by image analysis according to the procedure described later, and the particle diameter median value was determined from the particle size distribution and the number distribution ratio of fine particles was calculated. The results are shown in Table 1.

Note that the physical properties and other properties of the obtained colloidal silica were evaluated by the following methods.

### (1) SEM Observation:

The colloidal silica was diluted with water, placed on a silicon wafer sample stand, subjected to a drying treatment, and then observed using an ultra-high resolution field emission scanning electron microscope SU9000 manufactured by Hitachi High-Tech Corporation. The respective observation images of Examples 1 to 3 and 10 and Comparative Examples 1 to 4 are shown in FIGS. 2, 4, 6, 8, 10, 12, 14, and 16 (b).

### (2) STEM Observation:

The colloidal silica was diluted with water, placed on a supporting film for TEM, subjected to a drying treatment, and then observed using an ultra-high resolution field emission scanning electron microscope SU9000 manufactured by Hitachi High-Tech Corporation. The respective observation images (a) and analysis images (c) of Examples 1 to 3 and 10 and Comparative Examples 1 to 4 are shown in FIGS. 2 to 17.

### (3) Equivalent Circle Diameter and Particle Diameter Median Value:

The STEM image obtained in (2) was imported into the Image-Pro software of Hakuto Co., Ltd., the area of particles was measured, the results were imported into calculation software, the data of overlapping particles were removed by comparison with the SEM image taken at the same time, and the diameter calculated from the area of the remaining particles was used as the equivalent circle diameter. The equivalent circle diameters of all particles other than those removed were compiled, and the particle diameter for which the cumulative frequency (the number of particles) was exactly 50% was determined as the particle diameter median value. Then, those with a particle diameter of 50% or less of the particle diameter median value were defined as fine particles, and their number distribution ratio was determined. The particle diameter distributions (d) of Examples 1 to 3 and 10 and Comparative Examples 1 to 4 are shown in FIGS. 3, 5, 7, 9, 11, 13, 15 and 17.

(4) BET particle diameter: Measurement was performed using NOVA 4200e manufactured by Yuasa Ionics. The BET particle diameter is determined by obtaining the average particle diameter of spherical colloidal silica particles constituting the colloidal silica particles from the specific surface area S m²/g measured by the nitrogen adsorption method (BET method), using the expression D₂=2720/S.

(5) Zeta potential: Measurement was performed using the ZetaProbe zeta potential meter manufactured by Colloidal Dynamics LLC according to the zeta potential measurement method in high concentration colloidal solutions (solutions with post-production silica concentrations shown in Tables 1 to 2) based on the theory of ESA electric sonic phenomena.

(6) Average particle diameter nm: The median value of the particle size distribution measured using a disk centrifugal particle diameter distribution measurement apparatus manufactured by CPS Instruments, USA, was defined as the average particle diameter [nm].

(7) Silica concentration: The silica concentration was defined as the residue content after evaporation of the contained moisture.

(8) pH, viscosity, and electrical conductivity: Measurements were performed at 25° C.

(9) Metallic impurity content: Metallic impurities (total of Na, Fe, Cu, Al, K, Cr, Ni, Pb, Mn, Mg, Zn, and Ca) were measured in 50 g of the amount of sample collected, with an atomic absorption spectrophotometer.

TABLE 1

| | | | | Comparative | Comparative | Comparative | | Comparative |
|---|---|---|---|---|---|---|---|---|
| Item | Example 1 | Example 2 | Example 3 | Example 1 | Example 2 | Example 3 | Example 10 | Example 4 |
| The number of fine particles | 0 | 0 | 0 | 15 | 146 | 91 | 4 | 44 |
| (counts) | | | | | | | | |
| Proportion of fine particles (%) | 0 | 0 | 0 | 2.02 | 30.8 | 20.5 | 0.562 | 4.13 |
| The number of particles measured | 571 | 306 | 473 | 741 | 474 | 442 | 712 | 1064 |
| (counts) | | | | | | | | |
| Particle diameter median value | 32.8 | 49.4 | 69.0 | 33.7 | 46.5 | 66.4 | 37.5 | 21.7 |
| (nm) | | | | | | | | |
| The number of fields of view | 5 | 8 | 5 | 5 | 5 | 5 | 5 | 5 |
| Post-reaction silica concentration | 12.55 | 12.69 | 12.77 | 12.46 | 12.57 | 12.61 | 12.51 | 12.44 |
| (%) | | | | | | | | |
| Double pipe/single pipe | Double pipe | Double pipe | Double pipe | Single Pipe | Single Pipe | Single Pipe | Double pipe | Single Pipe |
| Outer pipe outer diameter (mm) | 25.4 | 25.4 | 25.4 | — | — | — | 25.4 | — |
| Outer pipe inner diameter O (mm) | 22.0 | 22.0 | 22.0 | — | — | — | 22.0 | — |
| Inner pipe outer diameter I (mm) | 6.35 | 6.35 | 6.35 | — | — | — | 6.35 | — |
| Inner pipe inner diameter (mm) | 3.50 | 3.50 | 3.50 | — | — | — | 3.50 | — |
| O/I | 3.46 | 3.46 | 3.46 | — | — | — | 3.46 | — |
| Outer pipe in-kettle length a (mm) | 723 | 723 | 723 | — | — | — | 723 | — |
| Inner pipe in-kettle length b (mm) | 553 | 553 | 553 | — | — | — | 553 | — |
| a − b (mm) | 170 | 170 | 170 | — | — | — | 170 | — |
| a − b/outer pipe outer diameter | 6.69 | 6.69 | 6.69 | — | — | — | 6.69 | — |
| Amount of nitrogen (L/min) | 0.5 | 0.5 | 0.5 | — | — | — | 0.5 | — |
| Feeding ultimate pressure of silica | 0 | 0 | 0 | 0 | 0 | 0 | 0 | 0 |
| source (MPa) | | | | | | | | |
| Post-production | | | | | | | | |
| Silica concentration % | 20.31 | 20.28 | 20.34 | 20.31 | 20.34 | 20.30 | 20.34 | 20.21 |
| pH | 7.72 | 8.18 | 8.43 | 7.76 | 8.20 | 8.39 | 7.6 | 7.07 |
| Electrical conductivity μS/cm | 250.0 | 165.4 | 124.7 | 246.0 | 164.0 | 121.6 | 123.0 | 72.7 |
| Zeta potential mV | −44.12 | −57.38 | −64.71 | −44.50 | −59.30 | −66.08 | −46.75 | −44.24 |
| Viscosity mPa · s | 4.65 | 3.57 | 3.40 | 5.30 | 3.63 | 3.56 | 4.49 | 4.11 |
| BET particle diameter nm | 17.7 | 30.3 | 36.2 | 17.4 | 29.8 | 38.9 | 26.99 | 27.92 |
| Average particle diameter nm | 35.6 | 52.6 | 71.2 | 35.3 | 53.6 | 72.5 | 39.9 | 46.5 |

TABLE 2

| Item | Example 4 | Example 5 | Example 6 | Example 7 | Example 8 | Example 9 |
|---|---|---|---|---|---|---|
| Double pipe/single | Double | Double | Double | Double | Double | Double |
| pipe | pipe | pipe | pipe | pipe | pipe | pipe |
| Outer pipe outer | 25.4 | 25.4 | 12.7 | 12.7 | 12.7 | 12.7 |
| diameter (mm) | | | | | | |
| Outer pipe inner | 22.0 | 22.0 | 10.0 | 10.0 | 10.0 | 10.0 |
| diameter O (mm) | | | | | | |
| Inner pipe outer | 6.35 | 6.35 | 6.35 | 6.35 | 6.35 | 6.35 |
| diameter I (mm) | | | | | | |
| Inner pipe inner | 3.50 | 3.50 | 3.50 | 3.50 | 3.50 | 3.50 |
| diameter (mm) | | | | | | |
| O/I | 3.46 | 3.46 | 1.57 | 1.57 | 1.57 | 1.57 |
| Outer pipe in-kettle | 723 | 723 | 723 | 723 | 723 | 723 |
| length a (mm) | | | | | | |
| Inner pipe in-kettle | 553 | 703 | 553 | 703 | 703 | 703 |
| length b (mm) | | | | | | |
| a − b (mm) | 170 | 20 | 170 | 20 | 20 | 20 |
| a − b/outer pipe outer | 6.69 | 0.787 | 13.4 | 1.57 | 1.57 | 1.57 |
| diameter | | | | | | |
| Amount of nitrogen | 1.0 | 4.0 | 4.0 | 0.5 | 1.0 | 4.0 |
| (L/min) | | | | | | |
| Feeding ultimate | 0 | 0.08 | 0.08 | 0.04 | 0.02 | 0.02 |
| pressure of silica | | | | | | |
| source (MPa) | | | | | | |
| Post-production | | | | | | |
| Silica concentration % | 20.30 | 20.26 | — | — | — | — |
| pH | 8.21 | 8.17 | — | — | — | — |
| Electrical conductivity | 160.7 | 165.7 | — | — | — | — |
| μS/cm | | | | | | |
| Zeta potential mV | −57.56 | −58.18 | — | — | — | — |
| Viscosity mPa · s | 3.78 | 3.58 | — | — | — | — |
| BET particle diameter | 29.1 | 29.0 | — | — | — | — |
| nm | | | | | | |
| Average particle | 57.7 | 53.1 | — | — | — | — |
| diameter nm | | | | | | |

### REFERENCE SIGNS LIST

1 . . . inner pipe; 2 . . . outer pipe; 3 . . . introduction pipe insertion slot; 4 . . . introduction pipe; 5 . . . reaction vessel; 6 . . . reaction solution; 7 . . . stirrer

1. A colloidal silica, wherein a number distribution ratio of fine particles having a particle diameter of 50% or less of a particle diameter median value based on an equivalent circle diameter (Heywood diameter) by image analysis using an electron microscope is 1% or less.

2. The colloidal silica according to claim 1, which is based on image analysis with a scanning electron microscope (SEM) and a scanning transmission electron microscope (STEM).

3. An abrasive comprising the colloidal silica according to claim 1.

4. A method for producing a colloidal silica, in which an easily hydrolyzable organosilicate is fed to and allowed to react with a reaction solution containing a hydrolysis catalyst composed of one or a mixture of two or more selected from organic amines,
wherein the feeding is performed with a feeding port of the easily hydrolyzable organosilicate immersed under a surface of the reaction solution.

5. The method for producing a colloidal silica according to claim 4, wherein a length of the feeding port of the easily hydrolyzable organosilicate immersed under a surface of the reaction solution is three or more times an outer diameter of the feeding port.

6. The method for producing a colloidal silica according to claim 4, wherein the easily hydrolyzable organosilicate is fed together with an inert gas.

7. The method for producing a colloidal silica according to claim 6, wherein a flow rate (L) of the inert gas relative to an amount (kg) of the easily hydrolyzable organosilicate fed is 1 to 10000 L/kg.

8. The method for producing a colloidal silica according to claim 4,
wherein a nozzle having an inner/outer double pipe structure with an outer pipe and an inner pipe inserted into the outer pipe is used as a means of feeding the easily hydrolyzable organosilicate, and
the inner pipe is fed with the easily hydrolyzable organosilicate and the outer pipe is fed with an inert gas.

9. The method for producing a colloidal silica according to claim 8, wherein a ratio of an inner diameter (O) of the outer pipe feeding the inert gas relative to an outer diameter (I) of the inner pipe feeding the easily hydrolyzable organosilicate, O/I, is 2 to 7.

10. The method for producing a colloidal silica according to claim 8, wherein a difference in length between the inner pipe feeding the easily hydrolyzable organosilicate and the outer pipe feeding the inert gas (outer pipe-inner pipe) is an outer diameter of the outer pipe or more, and is one or more times and ten or less times the outer diameter of the outer pipe.

11. The method for producing a colloidal silica according to claim 4, wherein the easily hydrolyzable organosilicate is trimethyl silicate, tetramethyl silicate, triethyl silicate, or methyl trimethyl silicate.

12. The method for producing a colloidal silica according to claim 4, wherein the organic amines are one or a mixture of two or more selected from quaternary ammoniums, tertiary amines, secondary amines, and primary amines, as well as carbonates, bicarbonates, and silicates thereof.

13. The method for producing a colloidal silica according to claim 6, wherein the inert gas is nitrogen, argon, and/or helium.

14. A method for producing a colloidal silica, in which a colloidal silica is produced by the method according to claim 4, and then using the colloidal silica as seed particles, an easily hydrolyzable organosilicate is fed to and allowed to react with a reaction solution containing the seed particles and the hydrolysis catalyst to produce a grown colloidal silica with a grown particle diameter.

15. The method for producing a colloidal silica according to claim 14, in which seed particles of colloidal silica with a particle diameter median value based on an equivalent circle diameter by image analysis using an electron microscope of 30 nm or less are used and allowed to react at a silica content concentration of 13% by mass or less in a reaction system to produce a grown colloidal silica in which the particle diameter median value is greater than 30 nm and 1 mm or less.
